(19) United States
(12) Patent Application Publication
(10) Pub. No.: US 2021/0224429 A1
(43) Pub. Date: Jul. 22, 2021

(54) Method, system for roadway intersection designs and computer program product

(71) Applicants: Amit Kumar Singh, Jabalpur (IN); Jiangling Wu, Kaifeng (CN)

(72) Inventors: Amit Kumar Singh, Jabalpur (IN); Jiangling Wu, Kaifeng (CN)

(21) Appl. No.: 16/747,529

(22) Filed: Jan. 21, 2020

(51) Int. Cl. G06F 30/13; E01C 1/02; E01C 1/00

(52) U.S. Cl. CPC G06F 30/13; E01C 1/002; E01C 1/02

(57) ABSTRACT

A computer program product for intersection design generation and evaluation method is provided. Intersection geometry, turning movement volume and design constraints are received from a user. All possible intersection designs are generated using iterative movement placement method provided. Intersection designs are filtered through design constraints. Total conflicting volume for each intersection designs are determined using two boundary methods provided. All intersection designs are ranked based on total conflicting volume. All possible intersection geometry, total critical volume and intersections ranks are provided to user as output.

### FIELD OF THE INVENTION

The present innovation relates to innovative roadway intersection designs.

### DESCRIPTION OF THE RELATED ART

The efficiency of an intersection design depends primarily on its ability to move the turning movement demand volume without any conflict. The innovative intersection designs are created by relocating or eliminating one or more movements with a high conflicting volume to secondary intersections. Left-turn movement at an intersection passes through the highest number of conflict points. Thus, the re-routed movements are often the high volume left turns. This allows multiple movements to go through the intersection simultaneously and increases intersection's efficiency.

There are approximately 10³³theoretically possible intersection designs for a typical four-legged intersection. The possible number of intersection designs at two closely spaced intersections are even higher. Detailed information about the theoretically possible intersection will be provided in greater detail hereinafter.

Before this invention, only a handful of innovative intersection designs have been proposed, studied and constructed during past several decades. A list of innovative intersections that are frequently considered during traffic analysis are: continuous green-T, quadrant roadway and its variations, partially displaced left turn and fully displaced left turn, restricted crossing U-turn, median U-turn, roundabouts, split intersection, echelon, center turn overpass, cloverleaf, contraflow left interchange, diverging diamond interchange, single point interchange, etc.

There are many possible intersection designs that has not been published before this invention. Some of the unknown intersection designs may be more efficient than any of the currently known intersection designs. Currently, only a limited number of intersection design options are known and used by highway agencies. Due to the limited number of available innovative intersection designs, the decision makers cannot be confident that the intersection design chosen is the best possible intersection design or there are other intersection designs that can provide better intersection operations. Hence, there is a need to consider all possible intersection designs to ensure that the best possible intersection design has been selected.

In order to compare the effectiveness of various intersection designs at a higher level, a generalized evaluation approach is needed, which can be applied to evaluate any intersection designs. One such generalized approach which has been quite popular among state and county highway agencies in the last five decades is critical lane analysis. Under critical lane analysis method, the intersections are evaluated by separating the turning movements into non-conflicting movement groups and summing up maximum demand volume from each non-conflicting movement group. Although critical lane analysis was proposed and developed during 1960's and 1970's, the detailed methodology was formally introduced in circular-212 by Transportation Research Board in 1980 and the Highway Capacity Manual 1985. Critical lane analysis was introduced to conduct a planning level analysis especially when the exact geometry of the intersection is not fully known. Since then, the critical lane analysis has been a crucial part of highway capacity manual to conduct a planning level intersection capacity analysis.

In the year 2009, the Federal Highway Administration's Office of Operations Research and Development has developed an extensive intersection evaluation tool known as “The Capacity Analysis for Planning of Junctions (Cap-X)”. The intersection and interchange design options available within the Cap-X tool are evaluated using the method of critical lane volume summation to provide planning-level capacity assessment of intersection designs. The Cap-X has emerged as a simple and cost-effective planning-level tool that helps users to select the most effective intersection and interchange designs. The latest version of Cap-X tool is Cap-X version 3.0. Cap-X version 3.0 is capable of evaluating sixteen at-grade intersection designs, two grade separated interception designs, seven roundabouts design and eight different interchange designs simultaneously.

There are several limitations of the current state-of-art intersection analysis tool, Cap-X. In order to use the critical lane analysis method, the design of intersection must be known beforehand. However, only a limited number of intersection designs are currently known. Additionally, in order to use the critical lane analysis method, the phasing scheme for the intersection designs has to be manually developed. Based on this manually developed phasing schemes, the total critical lane volume can be calculated for the intersection. It is practically impossible to develop phasing scheme manually for all possible intersection design. Hence, Cap-X cannot be extended to include every possible intersection designs. There is a need for a generalized critical lane methodology that can be applied to all intersection design without manual decision making Thus, there is a need for a system that can generate all possible intersection layout and compare their design efficiency.

### SUMMARY OF INVENTION

Broadly speaking, the invention is a technique which can generate and rank all possible intersection design layouts at an intersection for a given turning movement demand volume. This technique is implemented using a computer program. Input information is received by the user which includes information about one typical intersection layout, turning movement demand volume and other information that can affect efficiency of the intersection operation. An iterative movement switching mechanism is used to generate all possible intersection design options. The best possible phasing sequence for any given intersection design is generated within the system, and thus eliminates the need of manually developing phasing sequence for each intersection design. Dynamically generated phasing is used to determine the total conflicting volume for each intersection design.

Total intersection conflicting volume are determined using two approaches; boundary method-A and boundary method-B. Boundary method-A is focused on generating intersection designs which are more practical at the cost of generating less efficient intersection designs. Whereas, boundary method-B generates the most efficient intersection designs possible, without any consideration of additional requirements for the secondary intersections created at the boundary. The two methods differ in their principals and hence, have their own advantages and disadvantages for practical applications. Intersection designs are ranked based on their total conflicting volume. Two separate intersection design ranks are generated using boundary method-A and boundary method-B. Top intersection designs are sent back to the end user as output of the computer program.

The invention has been demonstrated through an example of a typical four-legged intersection. The top two intersection designs generated using boundary method-A approach are conventional intersection and partial displaced intersection. Both of these intersection designs are currently known and are used in practice. However, top two intersection designs generated using boundary method-B approach are two new intersection designs that has not been published before the invention.

This invention is expected to produce many more unknown intersection designs in the future. Additionally, this invention is robust and flexible which can be applied for many intersection variations. For example, the invention can be used to calculate the best intersection design for intersections with any number of legs. The invention can also be used to calculate optimal intersection layout for closely spaced intersections where two or more intersections operate together.

### BRIEF DESCRIPTION OF THE DRAWINGS

FIG. 1 is a flow diagram of intersection design generation and evaluation method system, in accordance with an embodiment of the invention.

FIG. 2 is a flow diagram illustrating the user input processing, in accordance with an embodiment of the invention.

FIG. 3 is a flow diagram illustrating a method to generate all feasible intersection designs, in accordance with an embodiment of the invention.

FIG. 4 is a flow diagram illustrating a method to evaluate all feasible intersection designs, in accordance with an embodiment of the invention.

FIG. 5 is a flow diagram illustrating the internal mechanism of conflicting volume computation engine, in accordance with an embodiment of the invention.

FIG. 6 is an exemplary four-legged intersection geometry input, in accordance with an embodiment of the invention.

FIG. 7 is a representative demand volume input at a typical four-legged intersection, in accordance with an embodiment of the invention.

FIG. 8 is the first ranked intersection design produced using the boundary method-A approach of the invention on a four-legged intersection example network, in accordance with an embodiment of the invention.

FIG. 9 is the second ranked intersection design produced using the boundary method-A approach within the invention on a four-legged intersection example network, in accordance with an embodiment of the invention.

FIG. 10 is the first ranked intersection design produced using the boundary method-B approach of the invention on a four-legged intersection example network, in accordance with an embodiment of the invention.

FIG. 11 is the second ranked intersection design produced using the boundary method-B approach within the invention on a four-legged intersection example network, in accordance with an embodiment of the invention.

### DETAILED DESCRIPTION OF THE INVENTION

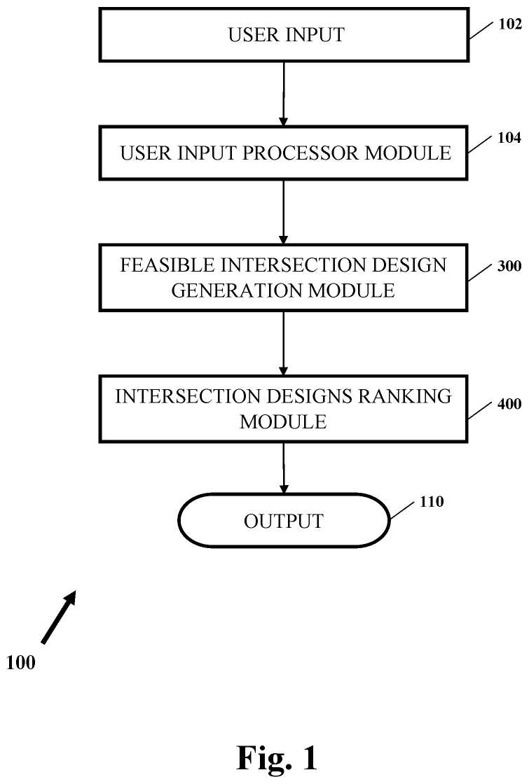

FIG. 1 illustrates a flow diagram of various modules that constitutes intersection design generation and evaluation method system 100, in accordance with one embodiment. As shown, user input 102 is received from an end user. The user input 102 contains information related to designs of a typical intersection layout, traffic demand volume and other information that can affect efficiency of the intersection operation. The user input 102 is passed to the user input processor module 104. The user input processor module 104 processes all the information provided by the user and generates new standard sets of information. Information generated by input processor module 104 is fed into feasible intersection design generation module 300. Feasible intersection design generation module 300 generates all possible intersection designs at the intersection. Next, newly created feasible intersection designs are evaluated using intersection designs ranking module 400. The best intersection design options and their evaluation results are then sent back to the user, as shown in operation 110.

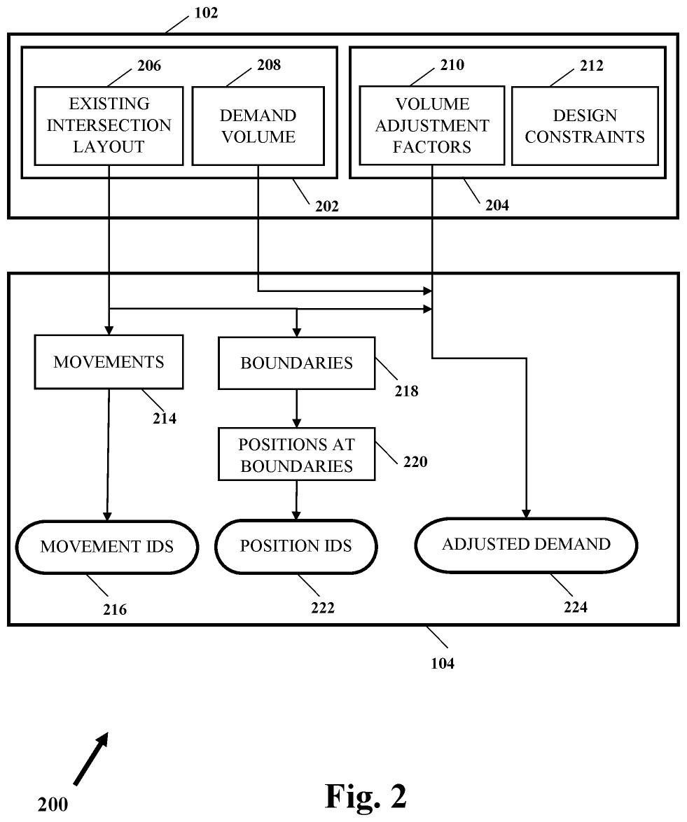

FIG. 2 shows the process of converting user information into a standard set of information 200 that is used within the intersection design generation and evaluation method system 100 computer program, in accordance with one embodiment. Input information 102 consists of two components, mandatory inputs 202 and optional inputs 204. Mandatory inputs 202 information are critical components of intersection design generation and evaluation method system 100, which the user must provide. The user can choose to provide the additional optional inputs 204.

Mandatory inputs 202 consists of two components, existing intersection layout 206 information and demand volume for each turning movement 208. The existing intersection layout 206 may include information such as intersection geometric, number of legs, number of lanes at each leg, position of each lane, number and type of lanes available for each turning movements etc. The optional inputs 204 also consists of two components, demand volume adjustment factors 210 and intersection design constraints 212. User may choose to provide information about one or both components of the optional inputs 204.

It should be noted that while intersection design generation and evaluation method system 100 can work without optional inputs 204, optional inputs 204 can be included within mandatory inputs 202. Under such conditions, both mandatory inputs 202 and optional inputs 204 is required to be provided by the user.

Input information 102 is sent to user input processor 104. Movements 214 at the intersections are extracted from the existing intersection layout 206 information. All the movements at the intersection are then assigned a unique movement ID s 216. Existing intersection layout 206 input also provides information about the boundaries 218 of the intersection. Based on the start and end positions of movements 214 at the boundary of the intersection, all positions 220 available for a movement to start or end are located. All positions are also assigned a unique position IDs 222. Each position within position IDs 222 represents a fixed location at the boundary of the intersection where a movement within movement IDs 214 can start or end. Each movement in movement IDs 216 has two positions from position IDs 222, which represents the start and end position of that movement at the intersection boundary 220. Hence, the number of positions within position IDs 222 are twice than the number of movements within movement IDs 216.

Traffic demand volume that can pass through an intersection within a given time depends on various factors such as the number of lanes available, type of turns vehicles has to make, counts of heavy vehicles etc. These factors are used to convert input demand volume 208 into the standard adjusted demand volume 224. Adjusted demand volume 224 are determined based on lane information available within existing intersection layout 206, traffic demand volume 208 and volume adjustment factors 210. The standard adjusted demand volume 224 for each movement are expressed in terms of the through movement demand volume per hour per lane. If demand volume adjustment factors have been provided by the user, then an adjustment to user input demand volume 208 is made to express the demand as equivalent number of cars in one lane going through the intersection. If the demand volume adjustment factors 210 are not provided by the user, no adjustments to the input demand volume 208 is made. Adjusted demand volume 224 is set equal to user input demand volume 208.

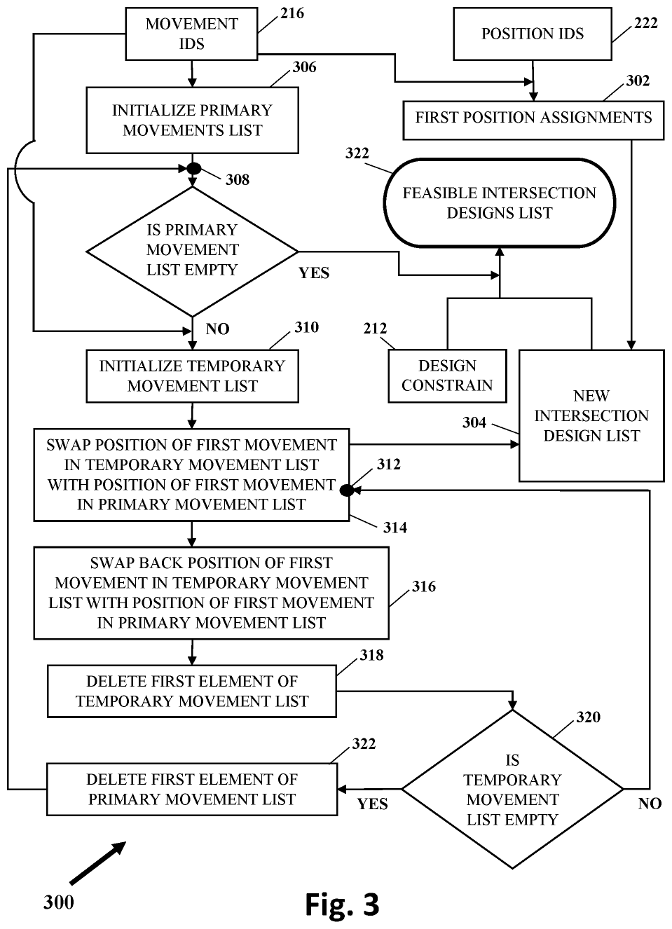

FIG. 3 is a detailed flow diagram of feasible intersection design generation module 300, in accordance with an embodiment of the invention. An intersection design is represented by two basic elements, movement ID and two position IDs assigned to each movement in movement IDs 216. New intersection design options are generated by iteratively changing position IDs of each movement in Movement IDs 216. This process creates different intersection layouts, where for each intersection layout, at-least one movement has a different position ID than rest of the intersection layouts.

It should be noted that when a movement is not located at its initial position, then secondary intersections are created at the boundary of the intersection. One secondary intersection can be created at each intersection boundary. The secondary intersections allow movements to deviate from their regular position within a typical intersection layout to a different position within new innovative intersection design. The secondary intersections are a crucial element of innovative intersection designs which makes these design more efficient than a typical intersection layout. For such innovative intersection designs the intersection provided by user is called ‘main intersection’, and intersections created at the boundaries are called ‘secondary intersections’. The procedure to evaluate the efficiency of intersection design based on the designs of main intersection and secondary intersections will be set forth hereinafter in greater detail.

First intersection layout 302 is same as the intersection layout provided by the user 206 as user input. First intersection layout 302 is simply the position IDs that are initially assigned to each movement of movements IDs 216. Positions ID of each movement IDs 216 corresponding to first intersection layout 302 is added to the new intersection design list 304.

A primary movement list 306 is generated which contains all movements presents within movement IDs 216. Next, the first iterative process 308 is started. At each stage of the first iterative process 308, the following steps are repeated until the primary movement list 306 gets empty. A temporary movement list 310 is generated which contains all the movements presents within Movement IDs 216.

Second iterative process 312 is started within the first iterative process 308. At the start of the second iterative process 312, the position ID of the first movement present in temporary movement list 310 is swapped with the position ID of first movement present in primary movement list 306, as shown in operation 314. This creates a new set of position IDs 222 assigned to two movements, one movement from the primary movement list 306 and one movement from the temporary movement list 310. This new sets of position IDs 222 represents a new possible intersection design layout. This set of new position IDs 222 are added to the new intersection design list 304.

At the next stage of the second iterative process 312, the position ID of the first movement present in temporary movement list 310 is swapped back with the position ID of the first movement present in primary movement list 306, as shown in operation 316. Then, the first movement of temporary movement list 310 is deleted, as shown in operation 318. The second iterative process 312, is repeated until the temporary movement list gets empty. Once temporary movement list 310 becomes empty, the first movement of the primary movement list is deleted and the second iterative process 312 is terminated, as shown in operation 320.

After second iterative process 312 is terminated, the first iterative process 308 is continued until primary movement list 306 gets empty. Every time the first iterative process is repeated, entire second iterative process 312 is also repeated. When the primary movement list 306 gets empty, then the first iterative process 308 is also terminated.

After terminating the first iterative process 308, the set of new intersection design list 304 is finalized. Some of the intersection design generated may not fit within intersection design constraints 212. Intersection designs that fit within design constraints 212 are selected and listed within feasible intersection designs list 322.

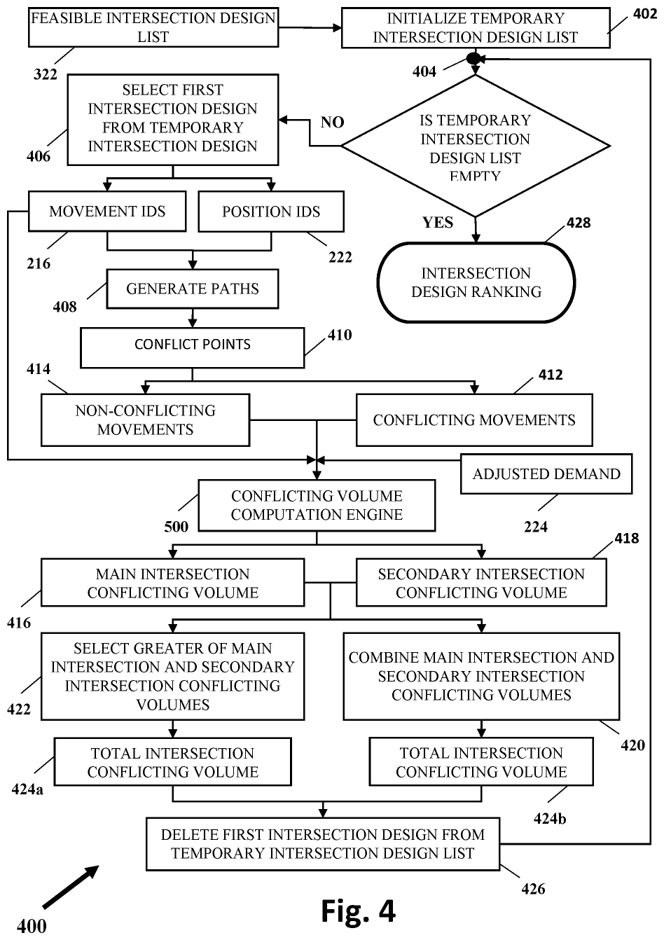

FIG. 4. is a detailed flow diagram of feasible intersection design ranking module 400, in accordance with an embodiment of the invention. Feasible intersection design ranking module 400 evaluates and ranks all intersection designs present in feasible intersection design list 322.

First, all feasible intersection designs within the feasible intersection designs list 322 are copied to a temporary intersection design list 402. Next, third iterative process 404 is started. At each stage of the third iterative process 404, the following steps are repeated until the temporary intersection design list 402 gets empty.

If temporary movement design list 402 is not empty, then first feasible intersection design within a temporary intersection design list 402 is selected, as shown in operation 406. Based on start and end position IDs 222 for each movement IDs 216 for the selected intersection design, movement paths 408 through the intersection are generated. Movement paths 408 are then used to determine conflict points 410 within the selected intersection design.

For each movement say movement-A within movement IDs 216, remaining movements within movement IDs 216 are divided into two separate sets, set of conflicting movements 412 and set of non-conflicting movements 414. The set of all movements whose paths are not crossing paths of movement-A, are listed under non-conflicting movements 414. Non-conflicting movements are movements that can go through the intersection simultaneously with movement-A at the intersection. The set of all other movements whose paths are crossing the path of the movement-A, are listed under conflicting movements 416. Conflicting movements 416 represents movements that cannot go simultaneously with the movement-A at the intersection.

Conflicting movements 416 and non-conflicting movements 414 along with adjusted demand volume 224 for each movement are sent to conflicting volume computation engine 500. Conflicting volume computation engine 500 provides the total conflicting volume at the intersection. Total Conflicting volume for the main intersection 416 and total conflicting volume 418 for the secondary intersections are determined separately using conflicting volume computation engine 500. Detailed information regarding components and the function of conflicting volume computation engine 500 will be provided hereinafter in greater detail.

Two different intersection design evaluating methods are used to select the best intersection designs; Boundary Method-A 420 and Boundary Method-B 422. In Boundary Method-A 420, the main intersection conflicting volume is combined with secondary intersection conflicting volume to determine total intersection conflicting volume 424a . In boundary Method-B, the maximum of the main intersection conflicting volume and the secondary intersection conflicting volume is taken as the total intersection conflicting volume 424b . The two methods differ in their principals and hence, have different uses. Boundary Method-A is focused on generating intersection designs which are more practical at the cost of less efficient intersection designs. Whereas Boundary Method-B generates the most efficient intersection designs, without any consideration of additional requirements for the additional intersections created at the boundary. The advantages and disadvantages of both methods will be further demonstrated through their application on a typical four-legged intersection hereinafter.

Next, the selected intersection design 406 is deleted from the temporary intersection design list 402, as shown in operation 426. The third iterative process 404 is repeated until all the feasible intersection designs within the temporary feasible intersection design list 402 are evaluated. After the temporary intersection design list 402 gets empty, third iterative process 404 is terminated.

After terminating the third iterative process 404, intersection design with the lowest total intersection conflicting volume is ranked first, intersection design with second lowest total intersection conflicting volume is ranked second and so on. For each feasible intersection designs within the feasible intersection designs list 322, two separate sets of intersection conflicting volume are recorded. Intersection conflicting volume 424a is obtained using boundary Method-A whereas Intersection conflicting volume 424a is obtained using boundary Method-B. For each feasible intersection design, two separate sets of intersection conflicting volume are used to develop two separate sets of intersection design rankings 428. Top selected intersection design along with its total intersection conflicting volume information is shown to the user as output, as shown in operation 110.

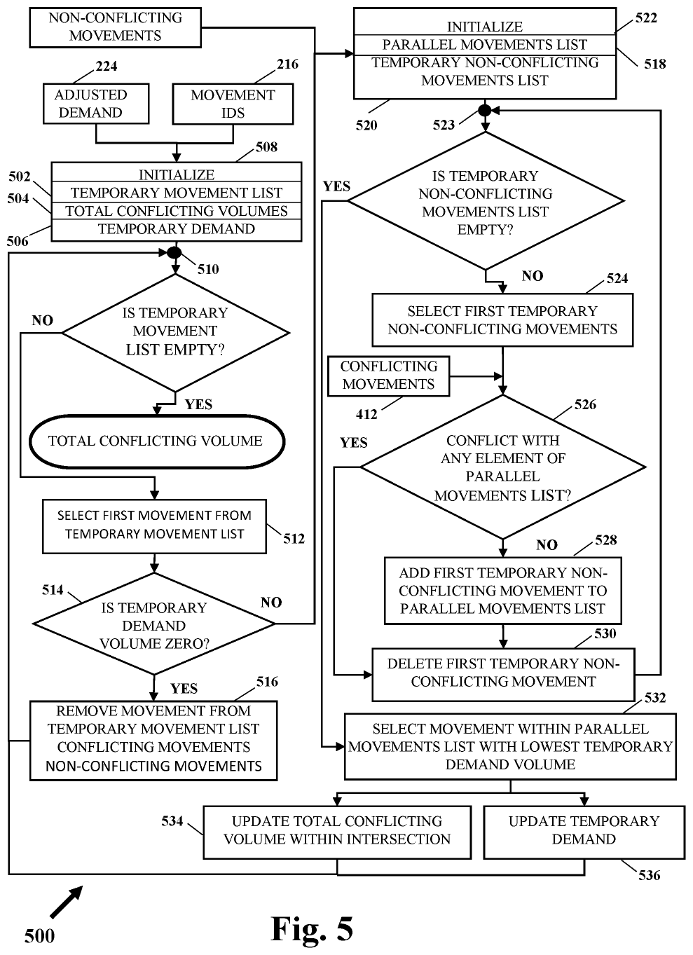

FIG. 5 is a detailed flow diagram of the conflicting volume computation engine 500, in accordance with an embodiment of the invention. This module determines the conflicting volume for any intersection design. First, temporary movement list 502, total conflicting volume 504 and temporary demand are created and initialized, as shown in operation 508. The temporary movement list 502 is initialized by copying all movements within the movement IDs 216 to the temporary movement list 502. The total conflicting volume 504 is initially set to zero. The temporary demand volume 506 is initialized by copying the adjusted demand volume 224 for each movement to the temporary demand volume 506.

Next, fourth iterative process 510 is started. At each stage of the fourth iterative process 510, the following steps are repeated until the temporary movement list 502 gets empty. If the temporary movement list 502 is not empty, then the first movement from temporary movement list say movement-B is selected, as shown in operation 512.

A check is made to see if there is any temporary demand volume 506 left for the selected movement-B, as shown in operation 514. If temporary demand volume 506 of selected movement-B is zero, then the selected movement-B is removed from the temporary movement list, and fourth iterative process 510 is repeated, as shown in operation 516. If temporary demand volume 506 for the selected movement-B is not zero, then there is still demand left at the selected movement B. If temporary demand volume 506 for the selected movement-B is not zero, then parallel movement list 518 and temporary non-conflicting movements list 520 are created and initialized, as shown in operation 522. The temporary non-conflicting movements list 520 is initialized by copying all the non-conflicting movements 414 for the selected movement-B. The parallel movement list 518 is initially empty.

A fifth iterative process 523 is started within the fourth iterative process 510. At each stage of the fifth iterative process 523, the following steps are repeated until the temporary non-conflicting movements list 520 gets empty. The first movement within temporary non-conflicting movement list 520 is selected, say movement-C, as shown in operation 524. Using the conflicting movement 412 information, it is checked whether the selected movement-C is in conflict with any of the movements within parallel movement list 520, as shown in operation 526. If the selected movement-C does not conflict with any of the movements within parallel movement list 520, then selected movement-C is added to parallel movement list 518, as shown in operation 528. Next, selected movement-C is deleted from the temporary non-conflicting movement list 520, as shown in operation 530. Fifth iterative process 213 is repeated until all movements within temporary non-conflicting movement list 520 are used. Once the temporary non-conflicting movement list 520 gets empty, the fifth iterative process 523 is terminated.

After the fifth iterative process 523 is terminated, the fourth iterative process 510 is continued. From all the movements within the parallel movement list 520, the movement with the lowest temporary demand volume 506 is selected, say movement-X, as shown in operation 532. The total conflicting volume 504 is set equal to the previous total conflicting volume plus the temporary demand volume of the selected movement-X, as shown in operation 534. The temporary demand volume 506 for each movement present in the parallel movement list 518 is set equal to their previous temporary demand volume minus the temporary demand volume of selected movement-X, as shown in operation 536.

Fourth iterative process 510 is repeated until temporary movement list gets empty 502. Once temporary movement list 502 gets empty, the total conflicting volume 504 is set equal to intersection conflicting volume 536. The intersection conflicting volume 536 is sent back as the output of the conflicting volume computation engine 500, as shown in operation 536.

FIG. 1, FIG. 2, FIG. 3, FIG. 4 and FIG. 5 provide comprehensive details about the steps that constitutes intersection design generation and evaluation method system 100. Next, the effectiveness and applicability of the invention is demonstrated by using the invention for an exemplary four-leg intersection. Details about the application and results of using the invention for the exemplary four-leg intersection are set forth hereinafter.

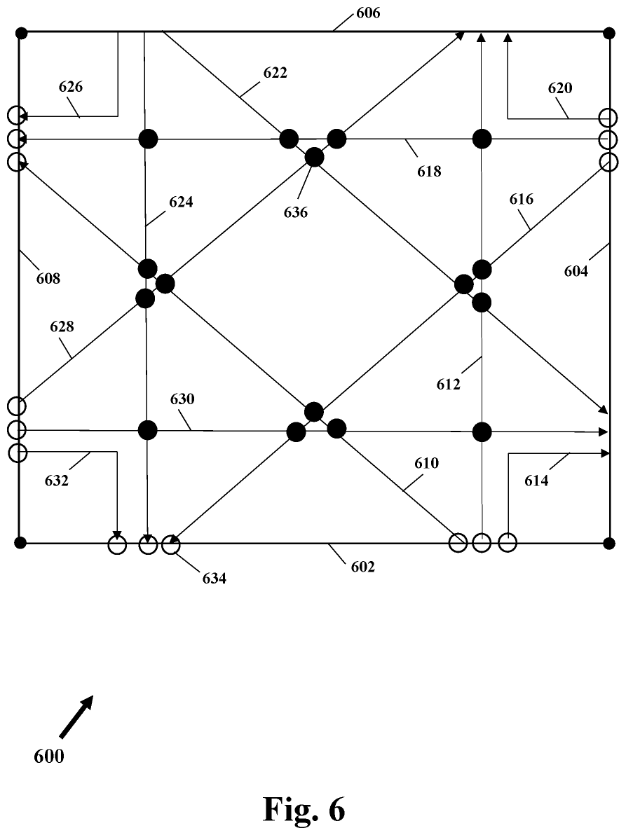

FIG. 6. shows a typical four-leg intersection layout 600 as an exemplary existing intersection layout 206 user input, in accordance with an embodiment of the invention. Intersection layout 600 has four outer boundaries, south boundary 602, east boundary 604, north boundary 606 and west boundary 608. These four outer boundaries are an example of boundaries 218. Intersection layout 600 consist of the following twelve movements, which is an example of movements 214.

Northbound left 610

Northbound through 612

Northbound right 614

Westbound left 616

Westbound through 618

Westbound right 620

Southbound left 622

Southbound through 624

Southbound right 626

Eastbound left 628

Eastbound through 630

Eastbound right 632

At each boundary, three movements start entering the intersection and three movements exits the intersection.

Movements northbound left 610, northbound through 612 and northbound right 614 starts at the south boundary 602. Movements southbound through 624, eastbound right 632 and westbound left 616 ends at the south boundary 602.

Movements westbound Left 616, westbound through 618 and westbound Right 620 starts at the east boundary 604. Movements southbound left 622, eastbound through 630 and northbound right 614 ends at the east boundary 604.

Movements southbound left 622, southbound through 624 and southbound right 626 starts at the north boundary 606. Movements westbound left 628, northbound through 612 and westbound right 620 ends at the north boundary 606.

Movements eastbound left 628, eastbound through 630 and eastbound right 632 starts at the west boundary 608. Movements northbound left 610, westbound through 618 and southbound right 626 movement ends at the west boundary 608.

Start and end positions 634 of movements are a fixed position at the boundaries. Twenty-four start and end positions 634 intersection layout 600 are an example of position IDs 222. The number of positions is twice the number of movements of the intersection. Movements within intersection layout 600 intersect with each other at sixteen conflict points 636. These sixteen conflict points 636 are an example of list of conflict points 410.

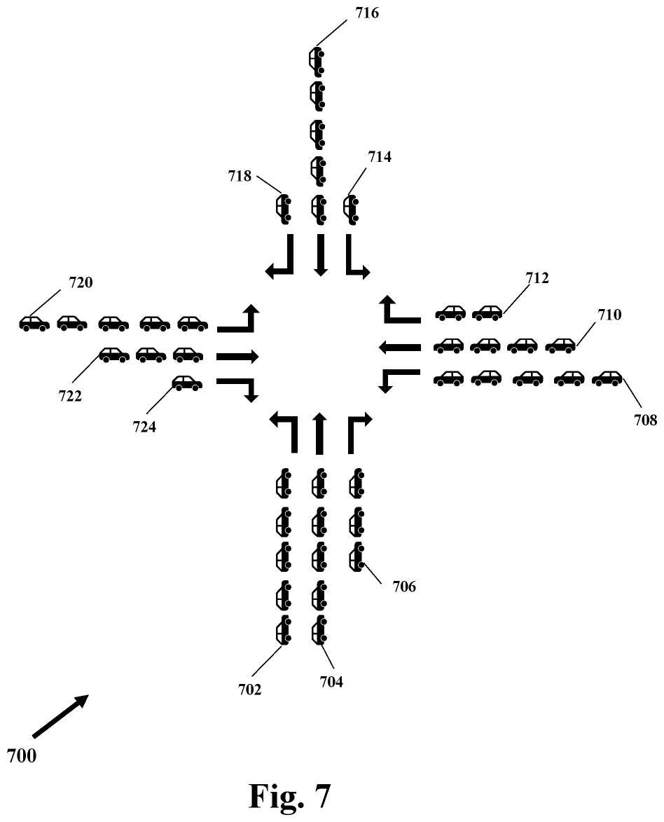

FIG. 7. Shows an exemplary demand volume 700 for each turning movement at the intersection as an exemplary demand volume user input 208, in accordance with an embodiment of the invention. These demand volume 700 contains information about the demand for each of twelve movements of intersection layout 600. Demand volume 700 for each movement of intersection layout 600 are as follows:

Northbound left 610 movement has a demand volume of five 702.

Northbound through 612 movement has a demand volume of five 704.

Northbound right 614 movement has a demand volume of three 706.

Westbound left 616 movement has a demand volume of five 708.

Westbound through 618 movement has a demand volume of four 710.

Westbound right 620 movement has a demand volume of two 712.

Southbound left 622 movement has a demand volume of one 714.

Southbound through 624 movement has a demand volume of five 716.

Southbound right 626 movement has a demand volume of one 718.

Eastbound left 628 movement has a demand volume of five 720.

Eastbound through 630 movement has a demand volume of three 722.

Eastbound right 632 movement has a demand volume of one 724.

Please note that the exemplary demand volume are presented here as an example only. Demand volume for real-life applications are usually higher than exemplary demand volume 700. The invention can be applied for any demand volume.

For simplicity this example does not include any volume adjustment factor 210. An exemplary design constraints is imposed on the final intersection designs. Design constraints specifies that each movements should start and end on the same side of their boundary as in typical intersection design. For example, movement northbound left 610 starts from south boundary 602 in an intersection design 600. So, within all feasible intersection designs, northbound left 610 should start from south boundary 602. This exemplary design constraint shows as example of the component design constraints 212.

Please note that if no design constraints are defined then all intersection design is a part of the feasible intersection designs and all intersection design would be evaluated. If the user has provided design constrains as provided in the current example, then only feasible intersection design would be evaluated.

Intersection design generation and evaluation method system 100 is used for the example intersection layout 600. Intersection layout 600, demand volume 700 and exemplary design constraints are sent to user input processor module 200. User input processor module 200 assigned unique ids to generate twelve movements and twenty-four position ids 634. Next, movement ids and positions ids 634 are sent to feasible intersection design module 300. By switching start and end positions 634 of the twelve movements, all feasible intersection designs 304 are created within feasible intersection design module 300. The number of design options can be calculated as:

Total possible intersection design for a four-legged intersection=(6*4)\hat{ }(6*4)≈1.3*10\hat{ }33 possible intersection designs

All intersection designs are tested one by one whether they met the exemplary design constraints. All intersections design that satisfy the design constrains are chosen to be a part of feasible intersection design list 322. The number of feasible intersection design options can be calculated as:

Total possible intersection design for a four-legged intersection=[(6*5*4*3*2)*(5*4*3*2)]\hat{ }2≈7*10\hat{ }9 possible feasible intersection designs

Next, all feasible intersection designs evaluated using intersection designs ranking module 400. Two set of ranking results were obtained using boundary method-A 420 and boundary method-B 422.

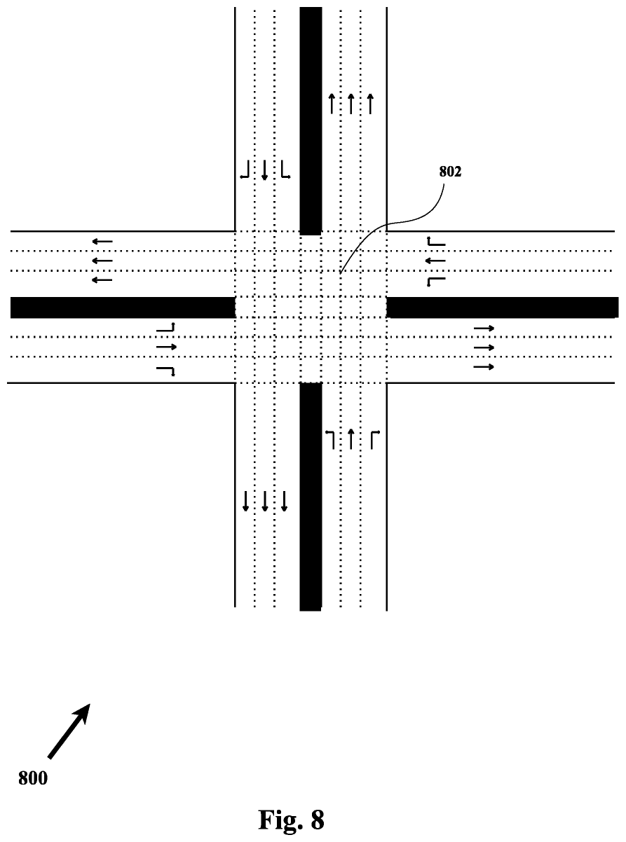

FIG. 8 shows the first ranked intersection design produced using the invention with Boundary Method-A 420 approach for intersection layout 600, in accordance with an embodiment of the invention. The first ranked intersection design is commonly known as the conventional four-legged intersection 800. The first ranked intersection design 800 is exactly same as user input intersection layout 600. Conventional four-legged intersection 800 does not create any additional conflicts at the boundary and accommodates all the conflicting demand volume within the main intersection itself. Conventional four-legged intersection design 800 does not require any additional right-of-way during its construction.

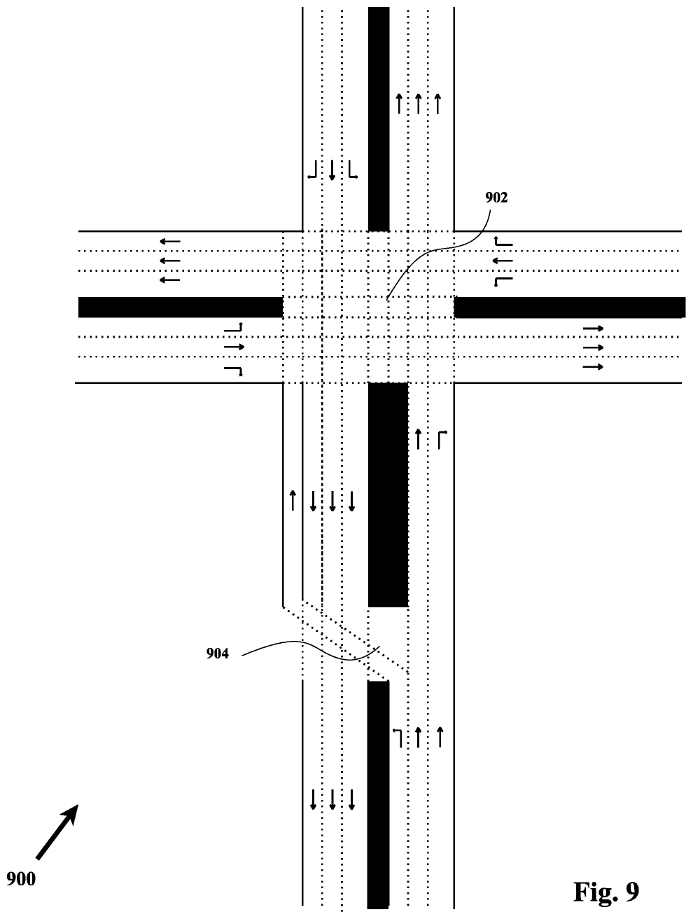

FIG. 9 shows the second ranked intersection design produced using the invention with Boundary Method-A 420 approach for intersection layout 600, in accordance with an embodiment of the invention. The second ranked intersection design is commonly known as one-legged partial displaced left turn 900 intersection design. One-legged north-leg displaced left turn 900 can re-route the high demand for the northbound left 702 movement through a path with less conflicting points. A secondary junction 904 is created where the northbound left movement 702 crossovers all the existing southbound movements. At the main intersection 906, the northbound left movement 610 can move simultaneously with northbound through 612, northbound right 614, southbound through 624 and southbound right 620 movements. This simultaneous movement reduces the total conflicting volume at the main intersection Similar to conventional four-legged intersection design 800, one-legged partial displaced left turn 900 intersection design only needs small additional right-of-way for its construction.

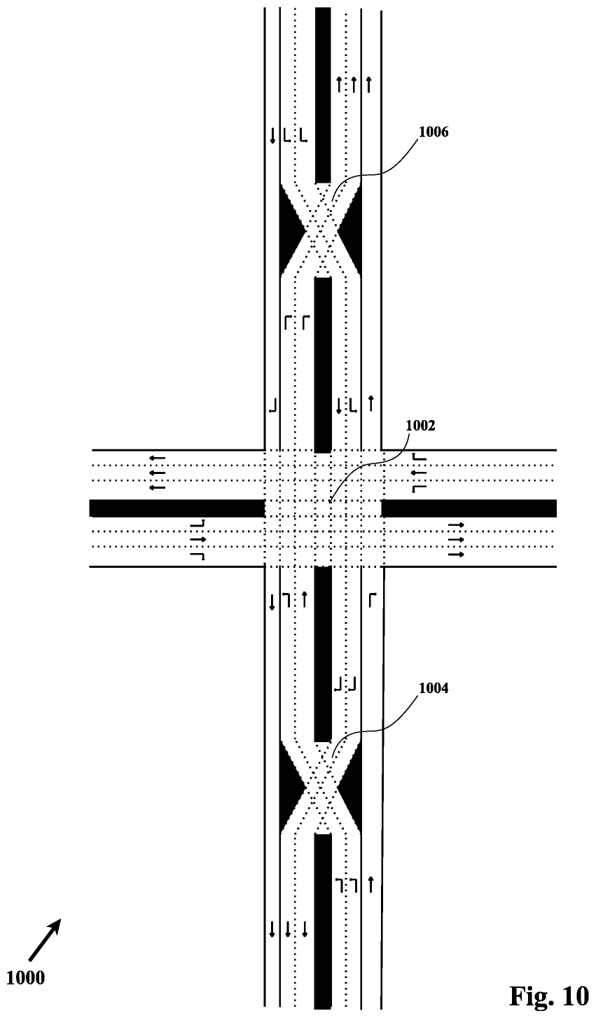

FIG. 10 shows the first ranked intersection design produced using the invention with Boundary Method-B 422 approach for intersection layout 600, in accordance with an embodiment of the invention. The first ranked intersection design is slightly similar to a north-south partial displaced left-turn intersection. This design is also similar to a Diverging Diamond Interchange with two intersections. To the inventor's knowledge, this intersection design which contains component of both partial displaced left turn and Diverging Diamond Interchange has not been published before. The first ranked intersection design produced using the invention with Boundary Method-B 422 will be referred to as “displaced left diverging diamond intersection” 1000 hereinafter.

The displaced left diverging diamond intersection 1000 has one main intersection 1002, and two secondary intersections. At the first secondary intersection located in south 1004, northbound left 610 and northbound through 612 movements crossover all the exiting southbound movements. At the second secondary intersection located in north 1006, the southbound left 622 and southbound through movement 624 crosses over all the northbound movements. This enables all six of the northbound and the south bound movements i.e. northbound left 610, northbound through 612, northbound right 614, southbound left 622, southbound through 624, and southbound right 626 to pass through the main intersection 1002 simultaneously. Additionally, northbound left 610, northbound through 612, northbound right 614, westbound left 622, southbound through 624, and southbound right 626 can also pass through the main intersection 1002 simultaneously. The ability of the displaced left diverging diamond 1000 intersection design to allow multiple simultaneous movements makes it a highly efficient intersection design.

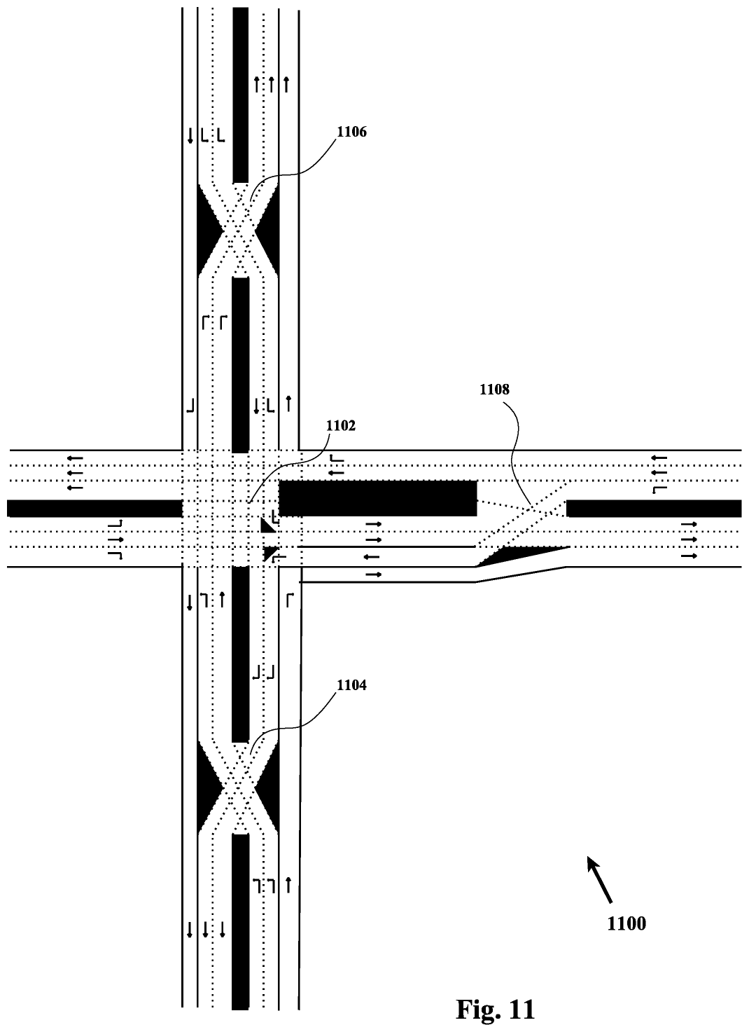

FIG. 11 shows the second ranked intersection design produced using the invention with Boundary Method-B 422 approach for intersection layout 600, in accordance with an embodiment of the invention. The second ranked intersection design is slightly similar to a north-south partial displaced left-turn intersection. This design is also similar to a contra-flow left turn intersection. To the inventor's knowledge, this intersection design which contains component of both partial displaced left turn and contraflow left turn has also not been published before. The second ranked intersection design produced using the invention with Boundary Method-B 422 will be referred as ‘displaced left contraflow intersection’ 1100 hereinafter.

The displaced left contraflow intersection 1100 is similar to the displaced left diverging diamond intersection 1000 except at its east boundary 604. Secondary intersection in south 1104 for displaced left contraflow intersection 1100 is same as the secondary intersection in south 1004 for the displaced left diverging diamond intersection 1000. Secondary intersection in north 1106 for displaced left contraflow intersection 1100 is same as the secondary intersection in north 1006 for the displaced left diverging diamond intersection 1000.

At the east boundary 604, displaced left contraflow intersection 1100 has a displaced left turn design 1108 at the secondary intersection 1108, where westbound left 616 movement crosses over all the eastbound movement before arriving at the main intersection 1102. This enables seven movements northbound left 610, northbound through 612, northbound right 614, southbound left 622, southbound through 624, southbound right 626 and westbound left 616 to pass through the main intersection 1102 simultaneously. Additionally, eastbound left 628 eastbound through 630, eastbound right, westbound left 616, westbound right 620 and south bound left 622 movement can also go simultaneously. The ability of the displaced left contraflow intersection 1100 design to pass various movements simultaneously makes it a highly efficient intersection design.

While various embodiments have been described above, it should be understood that they been presented by way of example only, and not limitation. For example, the invention can be applied for intersections with any number of legs and with any demand volume. Thus, the breadth and scope of a preferred embodiment should not be limited by any of the above-described exemplary embodiments but should be defined only in accordance with the following claims and their equivalent.

### REFRENCES CITED

### U.S. PATENT DOCUMENTS

1) F. D. Mier, B. H. Romo. Continuous flow intersection. United States Patent and Trademark Office. U.S. Pat. No. 5,049,000. Expired in 2003.

### OTHER PUBLICATIONS

1) Interim Materials on Highway Capacity. Transportation Research Circular 212. Transportation Research Board, Washington, D.C., 1980.
2) Highway Capacity Manual. Transportation Research Board, Washington, D.C., 1985.
3) T. Lochrane, J. Bared, and W. Zhang. Capacity Analysis for Planning of Junctions (CAP-X) Tool, Federal Highway Administration, 2009.
4) Jenior, P., Haas, P., Butsick, A., and Ray, B., Capacity Analysis for Planning of Junctions (CAP-X) Tool User Manual. Publication FHWA-SA-18-067, FHWA, US Department of Transportation, 2018.
5) Highway Capacity Manual 6. Transportation Research Board, Washington, D.C., 2016.

What is claimed is:

1. A computer-implemented intersection design generation and evaluation method system comprising:
receiving a user input including at least a typical intersection layout;
a demand volume for each movement at the intersection;
generating standard set of information;
generating all feasible intersection designs;
determining total conflicting volume for all feasible intersection design;
ranking all feasible intersection designs;
and forwarding the best intersection design layout with their evaluation results to the user;
wherein the user input includes information relating to designs of a typical intersection layout, traffic demand volume and other factors that can affect efficiency of the intersection operation;
wherein input processor module processes the information provided by the user and generates the standard set of information;
wherein the standard set of information is used by feasible intersection design module to generate all feasible intersection design;
wherein intersection designs are ranked based on their total conflicting volume.

2. A method as recited in claim 1 wherein standard set of information relating to movement, position and adjusted demand is generated.

3. A method as recited in claim 1 wherein new intersection designs is generated by re-arranging start and end positions of the movements.

4. A computer-generated method for generating all intersections designs, said method comprising:
computer code for identifying start and end positions of all movements at the intersection;
computer code for iteratively re-arranging the start and end positions of movements at the intersection;
and computer code for generating new intersection design using re-arranging the start and end positions of movements.

5. A roadway intersection design evaluation system as recited in claim 1, comprising:
receiving start and end positions information of all movements of an intersection design;
generating paths connecting start and end positions of each movement;
generating conflicting points within the intersection designs;
separating movements into conflicting movement group and non-conflicting movement group;
determining intersection conflicting volume at the main intersection and the secondary intersections;
consolidating total intersection conflicting volume;
and ranking intersection designs;
wherein conflict points are generated when paths of any two movements cross each other;
wherein the set of all movements whose paths are not crossing paths of a movement are listed under non-conflicting movements;
wherein the set of all other movements whose paths are crossing the path of a movement-A, are listed under conflicting movements;
wherein intersection design with the lower total intersection conflicting volume is ranked higher.

6. A method as recited in claim 5, wherein the main intersection conflicting volume is combined with secondary intersection conflicting volume to determine total intersection conflicting volume.

7. A method as recited in claim 5, the maximum of the main intersection conflicting volume and the secondary intersection conflicting volume is taken as the total intersection conflicting volume.

8. A roadway intersection conflicting volume computation engine, comprising the steps of:
receiving information relating to movement, position, adjusted demand, conflicting movements and non-conflicting movements of a roadway intersection design;
initializing temporary movement list, temporary demand volume and total conflicting volume;
selecting first movement from temporary movement list;
deleting movements with temporary demand of zero;
generating a list of parallel movements that do not conflict with said first movement;
selecting second movement with lowest temporary demand volume;
updating temporary demand volume;
updating total conflicting volume within the intersection;
and consolidating intersection conflicting volume;
wherein the temporary movement list is initialized by copying all movements to the temporary movement list;
wherein the total conflicting volume is initially set to zero;
wherein the temporary demand volume is initialized by copying the adjusted demand volume for each movement to the temporary demand volume;
wherein the any movements within the list of parallel movements do not conflict with said selected movement or any other movement within the list of parallel movements;
wherein said second movement is selected from all the movements within the parallel movement list;
wherein said second movement has the lowest temporary demand volume within the parallel movement list;
Wherein the total conflicting volume is set equal to the previous total conflicting volume plus the temporary demand volume of the said second movement;
Wherein the temporary demand volume for each movement present in the parallel movement list is set equal to their previous temporary demand volume minus the temporary demand volume of said second movement.

9. A method as recited in claim 8, parallel movement are grouped together and wherein total conflicting volume is updated based on the said second movement within parallel movement group with lowest temporary demand volume.

10. A four-legged roadway intersection design A four-legged roadway intersection design produced using claim 1, comprising:
four intersection legs;
each leg having three entering and three movements exiting the intersection;
one main intersection and two secondary intersection;
two secondary locations positioned on opposite legs of intersection;
northbound left and northbound through movements crossover all the exiting southbound movements at first secondary intersection;
and, southbound left and southbound through movement crossover all the exiting northbound movements at second secondary intersection;
northbound right and southbound right movements are provided through an exclusive lane;
wherein northbound left, northbound through, northbound right, southbound left, southbound through, and southbound right movements can pass through the main intersection simultaneously;
wherein northbound left, northbound through, northbound right, westbound left, southbound through, and southbound right movements can pass through the main intersection simultaneously.

11. A four-legged roadway intersection design produced using claim 1, comprising:
four intersection legs;
each leg having three entering and three movements exiting the intersection;
one main intersection and three secondary intersection;
northbound left and northbound through movements crossover all the exiting southbound movements at first secondary intersection;
southbound left and southbound through movement crossover all the exiting northbound movements at second secondary intersection;
southbound right movement is provided through an exclusive lane;
northbound right movement is provided through an exclusive lane;
northbound right movement joins the eastbound existing movement after the third secondary intersection;
and westbound left movement crosses over all the exiting eastbound movement at the third secondary intersection;
wherein northbound left, northbound through, northbound right, southbound left, southbound through, southbound right and westbound left movement can pass through the main intersection simultaneously.
